(19) United States
(12) Patent Application Publication
(10) Pub. No.: US 2024/0372511 A1
(43) Pub. Date: Nov. 7, 2024

(54) FEEDBACK-TUNING BASED VARIABLE GAIN AMPLIFIER

(71) Applicant: Apple Inc., Cupertino, CA (US)

(72) Inventors: Hongrui Wang, San Jose, CA (US); Reetika K Agarwal, San Jose, CA (US); James Mawdsley, Costa Mesa, CA (US); Abbas Komijani, Mountain View, CA (US)

(21) Appl. No.: 18/142,540

(22) Filed: May 2, 2023

(51) Int. Cl. H03F 1/56; H03F 1/32; H03G 3/30

(52) U.S. Cl. CPC H03F 1/565; H03F 1/3205; H03G 3/3042; H03F 2200/222; H03F 2200/387; H03F 2200/451; H03G 2201/103

(57) ABSTRACT

This disclosure is directed to an amplifier (e.g., a variable gain amplifier (VGA)) with improved linearity compared to other amplifiers. The amplifier may include degeneration inductors and a tunable degeneration resistor to generate amplified signals. The degeneration inductors and the tunable degeneration resistor may form a resonant circuit to improve linearity of the amplified signal at a desired frequency by reducing direct current (DC) components and harmonic components of the amplified signal having the desired frequency. Moreover, the amplifier may also generate the amplified signals with improved linearity at back-off output powers based on using the tunable degeneration resistor and the degeneration inductors. As such, the amplifier may include the degeneration inductors and the tunable degeneration resistor to generate the amplified signals having an output power across a range of output powers, such as a peak output power and one or multiple back-off output powers, with improved linearity.

### BACKGROUND

The present disclosure relates generally to wireless communication, and more specifically to amplifiers of radio frequency circuits facilitating the wireless communication.

In an electronic device, a transmitter and a receiver may each be coupled to one or more antennas to enable the electronic device to transmit and receive wireless signals. The transmitter and the receiver may each include various components including one or multiple amplifiers. The amplifiers may output amplified signals based on receiving input signals. For example, the amplifiers may amplify a signal received by the one or more antennas or amplify a signal for transmission by the one or more antennas. In some cases, one or more of the amplifiers may output the amplified signals with reduced linearity across a range of amplitude gains. For example, an amplifier may output the amplified signals with distorted amplitude and/or phase when operating in normal output power mode, reduced power mode (e.g., a power back-off mode), or both.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an amplifier circuit may include a first transistor having a gate coupled to an input impedance matching circuit, a drain coupled to an output impedance matching circuit, and a source coupled to a tunable resistor and a first inductor. The amplifier circuit may also include a second transistor having a gate coupled to the input impedance matching circuit, a drain coupled to the output impedance matching circuit, and a source coupled to the tunable resistor and a second inductor.

In another embodiment, an electronic device may include one or more antennas, a transmitter coupled to the one or more antennas, and a power source. The transmitter may include a first transistor having a first gate coupled to a first impedance matching circuit, a first drain coupled to a second impedance matching circuit, and a first source coupled to a tunable resistor and a first inductor. Moreover, the transistor may include a second transistor having a second gate coupled to the first impedance matching circuit, a second drain coupled to the second impedance matching circuit, and a source coupled to the tunable resistor and a second inductor. The power source may be coupled to the first drain and the second drain.

In yet another embodiment, an electronic device may include one or more antennas, a receiver coupled to the one or more antennas, and a power source. The receiver may include a first transistor having a first gate coupled to a first impedance matching circuit, a first drain coupled to a second impedance matching circuit, and a first source coupled to a tunable resistor and a first inductor. The receiver may also include a second transistor having a second gate coupled to the first impedance matching circuit, a second drain coupled to the second impedance matching circuit, and a second source coupled to the tunable resistor and a second inductor. The power source may be coupled to the first drain and the second drain.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure; and

FIG. 5 is a schematic diagram of a variable gain amplifier of FIGS. 3 and/or 4 with degeneration inductors and a tunable degeneration resistor, according to embodiments of the present disclosure;

FIG. 6 is a plot diagram of a gain of the amplifier of FIG. 5 compared to third order output intercept point (OIP3) and noise factor (NF) of the amplifier, according to embodiments of the present disclosure;

FIG. 7 is a first layout diagram of the variable gain amplifier of FIG. 5 with the degeneration inductors implemented in a loop form away from an input transformer of the variable gain amplifier, according to embodiments of the present disclosure; and

FIG. 8 is a second layout diagram of the variable gain amplifier of FIG. 5 with the degeneration inductors implemented in a FIG. 8 form with overlaid surface area over the input transformer, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to an amplifier (e.g., a variable gain amplifier (VGA)) with improved linearity compared to other amplifiers. The amplifier may include degeneration inductors and a tunable degeneration resistor to generate amplified signals (e.g., output signals) with improved linearity. The degeneration inductors and the tunable degeneration resistor may form a resonant circuit improving linearity of the amplified signal at a desired frequency (e.g., fundamental frequency). For example, the degeneration inductors may reduce an amplitude of harmonic signals (e.g., second order harmonic signals) of the amplified signals at a peak gain and reduced gains (e.g., back-off output power) of the amplifier.

The tunable degeneration resistor may have tunable resistance (e.g., electrical resistance) for adjusting the gain of the amplifier. For example, the amplifier may amplify input signals with increased gain when the resistance of the tunable degeneration resistor is decreased. Moreover, the amplifier may amplify the input signals with decreased gain when the resistance of the degeneration resistor is increased. The amplifier may generate the amplified signals with improved linearity at back-off output powers based on using the tunable degeneration resistor and the degeneration inductors. For example, the tunable degeneration resistor may adjust the gain of the amplifier with an improved linearity compared to other amplifiers across a range of gains and/or back-off output powers. As such, the amplifier may include the degeneration inductors and the tunable degeneration resistor to generate the amplified signals having an output power across a range of output powers, such as a peak output power and one or multiple back-off output powers, with improved linearity.

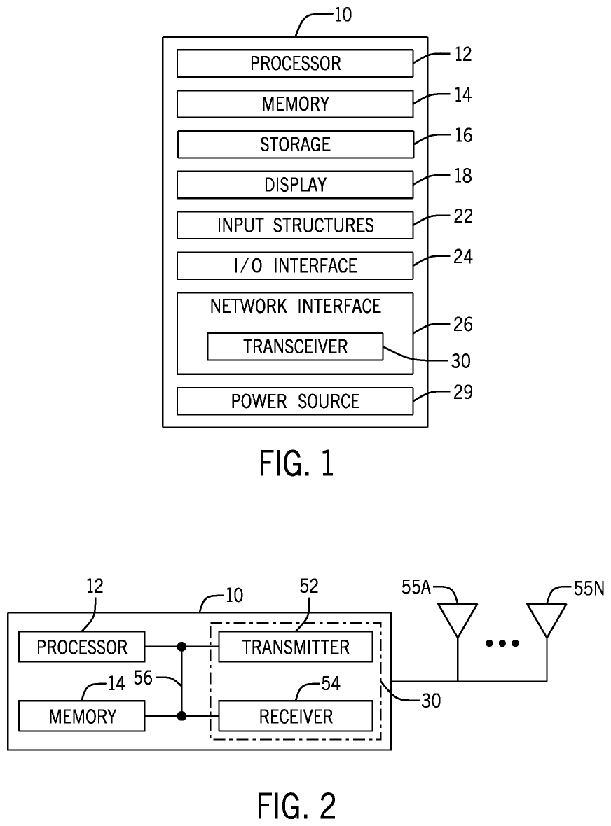

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. The power source 29 may provide input power to one or more components of the electronic device 10. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution® (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of electrical power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

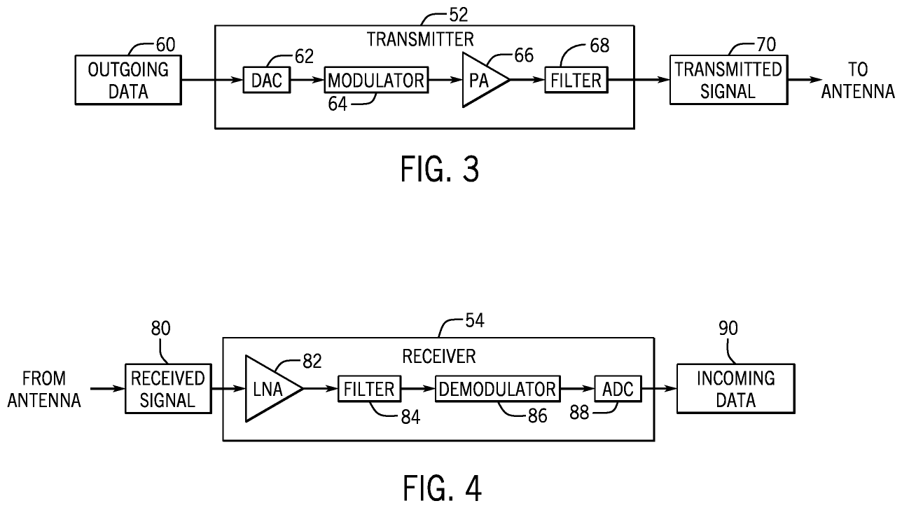

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (e.g., such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the amplified received analog signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

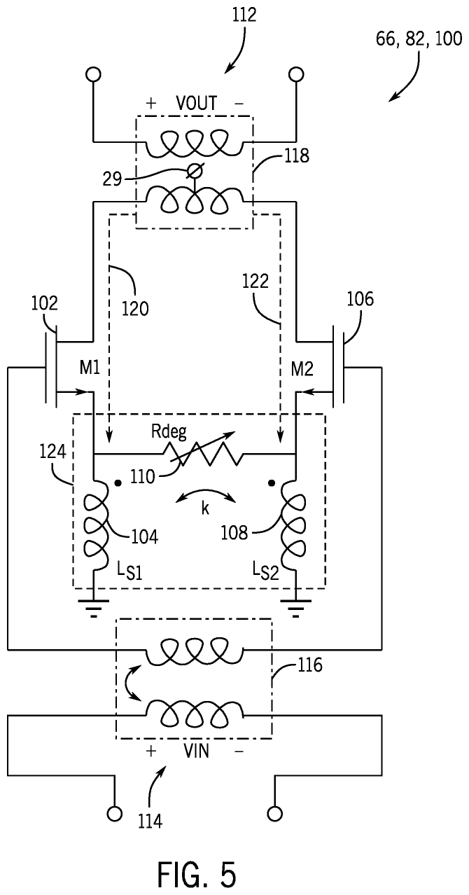

FIG. 5 is a schematic diagram of an amplifier 100 (e.g., a VGA) with a first transistor 102 (e.g., a first switch 102), a first inductor 104 (e.g., a first degeneration inductor 104, L_{S1}), a second transistor 106 (e.g., a second switch 106), a second inductor 108 (e.g., a second degeneration inductor 108, L_{S2}), and a tunable resistor 110 (e.g., a tunable resistance, a tunable degeneration resistor, or the like). The amplifier 100 may generate an amplified signal 112 (e.g., an output signal) based on receiving an input signal 114. In the depicted embodiment, sources of the first transistor 102 and the second transistor 106 are degenerated to improve linearity of an amplitude and/or a phase of the amplified signal 112 across a range of output powers. For example, the range of output powers may correspond to output powers below a first threshold and above a second threshold. In particular, the first inductor 104, the second inductor 108, and the tunable resistor 110 may improve linearity of the amplified signal 112 across a range of desired gains (e.g., −10 decibels (dB) to 0 dB, −3 dB to 3 dB, 0 to 10 dB, 3 to 20 dB, among other possibilities), as will be appreciated. For example, the range of output powers may correspond to output powers below a first power threshold and above a second power threshold. Moreover, the range of desired gains may correspond to gains below a first gain threshold and above a second gain threshold.

In some embodiments, the electronic device 10 discussed above may include the amplifier 100. For example, the PA 66 and/or the LNA 82 of the electronic device 10 may include the amplifier 100. An input impedance matching network 116 (e.g., an input port 116, an input impedance matching circuit 116) of the amplifier 100 may receive the input signal 114 such as the outgoing data 60 (e.g., analog converted and/or modulated signal 60) and/or the received signal 80. In different embodiments, the input impedance matching network 116 may receive the input signal 114 from different circuits (e.g., the filter 68, the antenna 55, the filter 84, the demodulator 86, among other things).

In some cases, the input impedance matching network 116 may provide an input impedance (e.g., a high impedance) for receiving the input signal 114. In the depicted embodiment, a first input coil of the input impedance matching network 116 may inductively couple to a second input coil of the input impedance matching network 116 to receive the input signal 114. It should be appreciated that in different embodiments, the input impedance matching network 116 may include any other viable circuit (e.g., transmission lines) for receiving the input signal 114.

The input impedance matching network 116 may be differentially coupled to gates of the first transistor 102 and the second transistor 106. It should be appreciated that in alternative or additional embodiments, the input impedance matching network 116 may also couple to one or more single-ended degenerated transistors. For example, in such embodiments, a source of each of the single-ended degenerated transistors may be coupled to one or more degeneration inductors and one or more tunable degeneration resistors (e.g., in parallel to each other).

In any case, in the depicted embodiment, a source of the first transistor 102 is coupled to the first inductor 104 and a first side of the tunable resistor 110. Moreover, a source of the second transistor 106 is coupled to the second inductor 108 and a second side of the tunable resistor 110. The first inductor 104 and the second inductor 108 may inductively couple based on a coupling factor k (e.g., negative coupling factor) during operation of the amplifier 100. For example, the first inductor 104 and the second inductor 108 may be disposed in proximity of each other to inductively couple during operation of the amplifier 100.

In some embodiments, the tunable resistor 110 may include an array of parallel switches (e.g., transistors). In alternative or additional embodiments, the tunable resistor 110 may include different circuitry. Moreover, in some cases, the tunable resistor 110 may be coupled to the processor 12 and/or any other viable processor and/or controller.

For example, the processor 12 may generate control signals to adjust a resistance (e.g., an electrical resistance) of the tunable resistor 110 to a desirable level. The processor 12 may provide the control signals to the tunable resistor 110 for increasing the resistance of the tunable resistor 110 to decrease a gain and therefore decrease an output power of the amplifier 100. Moreover, the processor 12 may provide the control signals to the tunable resistor 110 for decreasing the resistance of the tunable resistor 110 to increase the gain and therefore increase the output power of the amplifier 100. In different embodiments, the tunable resistor 110 may have different range of resistance values (e.g., values of the resistance, values of the electrical resistance) equal to and/or above a low resistance threshold and equal to and/or below a high resistance threshold (e.g., 1-100Ω, 50-200Ω, 1-1000Ω, 50-2000Ω, and so on). In some cases, the low resistance threshold may correspond to a peak gain and therefore a high (e.g., increased, maximum) output power of the amplifier 100 for outputting the amplified signal 112. Moreover, the high resistance threshold may correspond to a low gain (e.g., minimum gain, a gain of near 1) and therefore a low (e.g., decreased, minimum) output power of the amplifier 100 for outputting the amplified signal 112.

Drains of the first transistor 102 and the second transistor 106 are coupled to different sides of an output impedance matching network 118 (e.g., an output port 118, an output impedance matching circuit 118) of the amplifier 100. The output impedance matching network 118 may output the amplified signal 112. The output impedance matching network 118 may include a first output coil disposed on the amplifier 100 and a second output coil disposed on the circuit coupled to the amplifier 100 (e.g., a load circuit) receiving the amplified signal 112 (e.g., the filter 68, the filter 84, the demodulator, 86, the antenna 55, among other things). In some cases, the output impedance matching network 118 may provide an output impedance (e.g., a high impedance) for providing the amplified signal 112.

In the depicted embodiment, the power source 29 may be coupled to the output impedance matching network 118. As such, the power source 29 may provide a direct current (DC) signal to the first transistor 102 and the second transistor 106 during operation of the amplifier 100. The DC signal may have a zero (e.g., near zero) frequency. Moreover, the first transistor 102 and the second transistor 106 may conduct the DC signal to a ground connection (e.g., ground the DC signal) based on receiving the input signal 114.

The first transistor 102 and the second transistor 106 may provide the DC signal with a varying amplitude based on oscillations of the input signal 114 at the gates of the first transistor 102 and the second transistor 106. In particular, the first transistor 102 and the second transistor 106 may conduct a varying amount of the electrical current based on a varying amplitude of the input signal 114 corresponding to a desired frequency (e.g., such that noise in the amplified signal is below a threshold, such that filtering of the amplified signal may be unnecessary, including a fundamental frequency, F₀) for receiving the input signal 114. As such, the varying amplitude of the input signal 114 may correspond to the frequency of the input signal 114. For example, the first transistor 102 and the second transistor 106 may pass-through an increased amount of the electrical current at positive half-cycles of the input signal 114 based on an increased conductivity of the first transistor 102 and the second transistor 106. Moreover, the first transistor 102 and the second transistor 106 may pass-through a decreased amount of the electrical current at negative half-cycles of the input signal 114 based on a decreased conductivity of the first transistor 102 and the second transistor 106.

Accordingly, the first transistor 102 may provide a first drain-to-source signal 120 having the frequency of the input signal 114 during operation. Moreover, the second transistor 106 may provide a second drain-to-source signal 122 having the frequency of the input signal 114 during operation. Although N-channel transistors 102 and 106 are shown in the depicted embodiment, it should be appreciated that in alternative or additional embodiments, the amplifier 100 may include any other viable switching circuit such as P-channel transistors, among other things. Moreover, although the power source 29 is coupled to the first output coil of the output impedance matching network 118, it should be appreciated that in alternative or additional embodiments, the power source 29 may be coupled to the amplifier 100 in any other viable form.

With the foregoing in mind, the first inductor 104, the second inductor 108, and the tunable resistor 110 may form a resonant circuit 124. The resonant circuit 124 may provide a DC impedance Z_{DC} to DC components of the first drain-to-source signal 120 and the second drain-to-source signal 122 having a DC frequency (e.g., 0 hertz, near 0 hertz) based on equation 1:

$${Z}_{D C} = {R}_{L S} \approx 0 \qquad Equation 1$$

The DC impedance Z_{DC} corresponds to a resistance of the first inductor 104 and/or the second inductor 108 (R_{LS}). Moreover, the first inductor 104 and the second inductor 108 may include conductive materials. Accordingly, the resonant circuit 124 may provide low impedance (e.g., 0Ω, near 0Ω, less than 100Ω, and so on) to DC components of the first drain-to-source signal 120 and the second drain-to-source signal 122 (e.g., common-mode signals). For example, the resonant circuit 124 may ground the DC components of the first drain-to-source signal 120 and the second drain-to-source signal 122 (e.g., common-mode signals). In some cases, the ground the DC components, ground the harmonic components, or both.

The resonant circuit 124 may provide an impedance Z_{F0} to signals having the desired frequency F₀ based on equation 2:

$${Z}_{F 0} = {R}_{deg} \qquad Equation 2$$

The impedance Z_{F0} of the resonant circuit 124 may correspond to a resistance value R_{deg} (e.g., a value of the resistance, a value of the electrical resistance) of the tunable resistor 110. That is, tuning the tunable resistor 110 may correspond to tuning the impedance Z_{F0}. Accordingly, the tunable resistor 110 may also adjust the gain of the amplifier 100 with an improved linearity compared to other amplifiers across a range of gains G associated with peak gain and the back-off output powers. The gain G of the amplifier 100 may be determined based on equation 3:

$$G = \frac{{g}_{m} * {Z}_{L}}{1 + ( {g}_{m} * {R}_{deg} )} \qquad Equation 3$$

A transconductance of the transistor may correspond to gₘ in equation 3. A load impedance Z_{L} may correspond to an impedance of the load circuit coupled to the output impedance matching network 118. As such, adjusting the resistance value R_{deg} of the tunable resistor 110 may adjust a dynamic gain of the amplifier 100 (e.g., with a dynamic range of the amplifier 100). Moreover, and as mentioned above, the processor 12 and/or any other viable controller and/or processor may provide the control signals to adjust the resistance value R_{deg} of the tunable resistor 110. The processor 12 may decrease the resistance value R_{deg} of the tunable resistor 110 (e.g., the degenerative resistor) to increase the gain of the amplifier 100 based on decreasing feedback (e.g., negative feedback) of the amplifier 100. Moreover, the processor 12 may increase the resistance value R_{deg} of the tunable resistor 110 to reduce the gain of the amplifier 100 based on increasing the feedback of the amplifier 100.

In specific embodiments, the feedback may reduce at least some signal distortions to improve stability of the amplified signal 112. Moreover, the feedback may linearize the transfer characteristics of the first transistor 102 and the second transistor 106. Accordingly, the amplifier 100 may generate the amplified signal 112 with improved linearity at back-off output powers based on increasing the resistance value R_{deg} of the tunable resistor 110 (e.g., increasing the feedback). For example, based on the gain G of the amplifier 100 discussed above with respect to equation 3, a back-off gain G_{back-off} of the amplifier 100 may be determined based on equation 4:

$${G}_{back - off} = \frac{{Z}_{L}}{{R}_{deg}} \qquad Equation 4$$

In some cases, the processor 12 may decrease the resistance value R_{deg} of the tunable resistor 110 to a low resistance (e.g., 0Ω, near 0Ω, less than 100Ω, and so on) for a peak gain Gₚₑₐₖ of the amplifier 100. In such cases, the peak gain Gₚₑₐₖ may be determined based on the transconductance of the transistor gₘ and the load impedance Z_{L} based on equation 5:

$${G}_{peak} = {g}_{m} * {Z}_{L} \qquad Equation 5$$

Moreover, the resonant circuit 124 may provide a harmonic impedance Z_{2F0} to harmonic signals of the first drain-to-source signal 120 and the second drain-to-source signal 122. The harmonic signals may have frequency components that are multiples of the desired frequency F₀ (e.g., twice the desired frequency F₀). In some cases, the harmonic impedance Z_{2F0} of such harmonic signals (e.g., second harmonic signals) may be determined based on the equation 6:

$${Z}_{2 F 0} = 2 * ω * {L}_{S} ( 1 + k ) \qquad Equation 6$$

An angular frequency ω may be determined based on the desired frequency F₀. The inductance L_{S} may correspond to an inductance of the first inductor 104 and the second inductor 108. For example, in some cases, the first inductor 104 and the second inductor 108 may have the same inductance L_{S}. In alternative or additional cases, the first inductor 104 and the second inductor 108 may have different inductances L_{S1} and L_{S2}. In such cases, the inductance L_{S} of equation may correspond to (or derived from) the inductances L_{S1} and L_{S2}.

As such, the inductance L_{S}, the coupling factor k, and the desired frequency F₀ may correspond to the harmonic impedance Z_{2F0} for reducing (e.g., rejecting) harmonic signals (e.g., second harmonic signals) of the first drain-to-source signal 120 and the second drain-to-source signal 122. In specific cases, the inductance L_{S}, the coupling factor k, and the desired frequency F₀ may be determined (e.g., selected) such that at least some of the second harmonic signals 2F₀ of the first drain-to-source signal 120 and the second drain-to-source signal 122 may be rejected during operation of the amplifier 100. Accordingly, the amplifier 100 may include the first inductor 104, the second inductor 108, and the tunable resistor 110 to generate the amplified signal 112 having an output power across a range of output powers, such as a peak output power and one or multiple back-off output powers, with improved linearity.

The first inductor 104 and the second inductor 108 may be implemented to have the coupling factor k having different values. For example, in some cases, the first inductor 104 and the second inductor 108 may be implemented to have the coupling factor k near −1 to reduce the harmonic impedance Z_{2F0} for the harmonic signals (e.g., second harmonic signals) near 0. In any case, the coupling factor k (and/or the inductance L_{S}) may be selected such that the harmonic signals and/or intermodulation distortions (IM3) of the amplified signal 112 having the desired frequency F₀ is reduced.

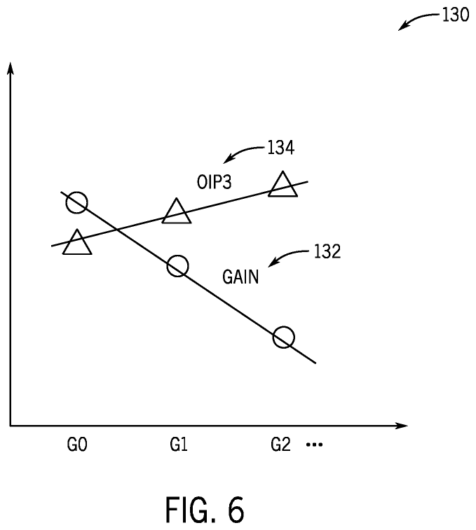

FIG. 6 is a plot diagram 130 of a gain 132 of the amplifier 100 compared to third order output intercept point (OIP3) 134 of the amplifier. In particular, gains 132 of the amplifier 100 is shown including a range of gains G0 (e.g., peak gain Gₚₑₐₖ), G1 (e.g., first back-off gain G_{back-off}), and G2 (e.g., second back-off gain G_{back-off}) compared to the OIP3 134. As discussed above, tuning the tunable resistor 110 may correspond to adjusting the gain 132 of the amplifier 100 with an improved linearity compared to other amplifiers across a range of gains G. For example, increasing the tunable resistor 110 may reduce the gains G0 to G1 or G2. In the depicted embodiment, OIP3 134 may be improved (e.g., increased) at G1 and G2 to improve linearity of the amplified signal 112.

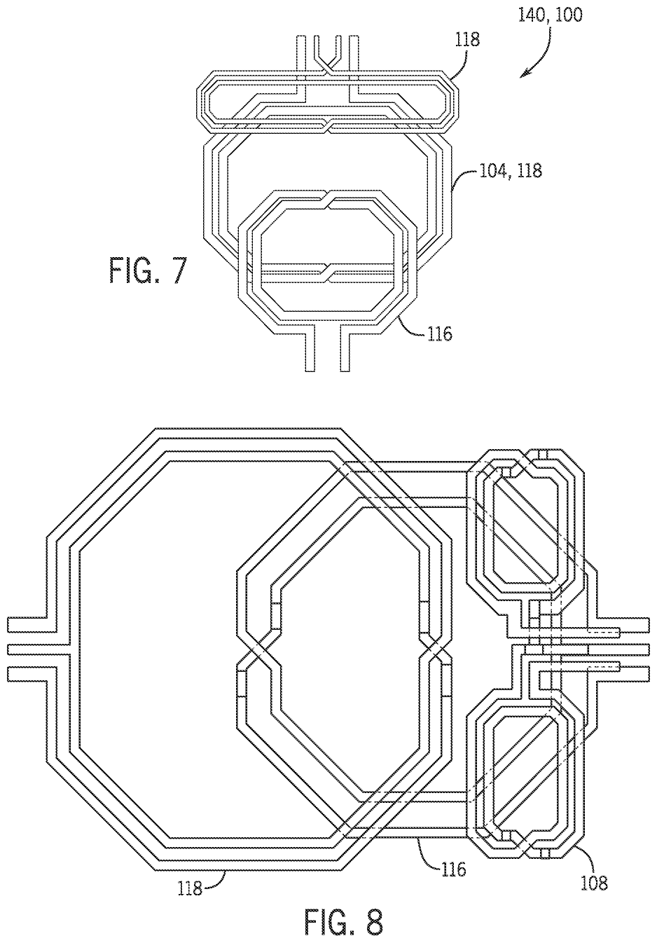

FIGS. 7 and 8 depict different layout diagrams 140 and 150 of the first inductor 104, the second inductor 108, input impedance matching network 116 (e.g., input transformer), and output impedance matching network 118 (e.g., output transformer) of the amplifier 100 discussed above. In particular, the layout diagram 140 depicts the amplifier 100 with the first inductor 104 and the second inductor 108 implemented in a loop form away from the input impedance matching network 116.

In some embodiments, the first inductor 104 and the second inductor 108 may be overlaid, intertwined, and/or disposed around each other. Moreover, the layout diagram 150 depicts the amplifier 100 with the first inductor 104 and the second inductor 108 implemented in a FIG. 8 form with overlaid surface area over the input transformer. In FIG. 8, the output impedance matching network 118 at least partially overlaps (e.g., is positioned over, on top of, underneath of, and so on) the input impedance matching network 116. Similarly, the input impedance matching network 116 at least partially overlaps (e.g., is positioned over, on top of, underneath of, and so on) the second inductor 108, where overlapping portions of the input impedance matching network 116 with respect to the second inductor 108 are illustrated with dashed lines.

For example, the layout diagrams 140 and 150 depict two possible layouts for implementing the first inductor 104 and the second inductor 108 having the coupling factor k near −1 to reduce the harmonic impedance Z_{2F0} for the harmonic signals (e.g., second harmonic signals) near 0. As discussed above, the coupling factor k (and/or the inductance L_{S}) may be selected such that the harmonic signals and/or the intermodulation distortions (IM3) of the amplified signal 112 having the desired frequency F₀ is reduced to improve linearity of the amplified signal 112 across a range of output powers. It should be appreciated that alternative layout diagrams may be envisioned.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. An amplifier comprising:
a first transistor having a gate coupled to an input impedance matching circuit, a drain coupled to an output impedance matching circuit, and a source coupled to a tunable resistor and a first inductor; and
a second transistor having a gate coupled to the input impedance matching circuit, a drain coupled to the output impedance matching circuit, and a source coupled to the tunable resistor and a second inductor.

2. The amplifier of claim 1, wherein the tunable resistor is configured to receive one or more control signals indicative of a resistance value, from one or more processors.

3. The amplifier of claim 2, wherein the tunable resistor is configured to provide an electrical resistance corresponding to the resistance value.

4. The amplifier of claim 1, wherein the tunable resistor is configured to provide an electrical resistance below a first resistance threshold associated with an increased gain of the amplifier for generating amplified signals and above a second resistance threshold associated with a reduced gain of the amplifier for generating the amplified signals.

5. The amplifier of claim 1, wherein the tunable resistor comprises an array of transistors adjustable to provide a desired electrical resistance.

6. The amplifier of claim 1, wherein the first inductor and the second inductor are configured to inductively couple with a negative coupling factor during operation of the amplifier.

7. The amplifier of claim 1, wherein the drain of the first transistor and the drain of the second transistor are configured to couple to a power source, wherein the first transistor is configured to provide a first drain-to-source signal from the power source to the first inductor and the second transistor is configured to provide a second drain-to-source signal from the power source to the second inductor based on an input signal having a desired frequency.

8. The amplifier of claim 7, wherein the first inductor, the second inductor, and the tunable resistor form a resonant circuit, the resonant circuit configured to ground direct current (DC) components of the first drain-to-source signal and the second drain-to-source signal, and provide an electrical resistance to desired frequency components of the first drain-to-source signal and the second drain-to-source signal.

9. The amplifier of claim 8, wherein the resonant circuit is configured to ground one or more harmonic components of the first drain-to-source signal and the second drain-to-source signal.

10. An electronic device comprising:
one or more antennas;
a transmitter coupled to the one or more antennas and comprising
a first transistor having a first gate coupled to a first impedance matching circuit, a first drain coupled to a second impedance matching circuit, and a first source coupled to a tunable resistor and a first inductor, and
a second transistor having a second gate coupled to the first impedance matching circuit, a second drain coupled to the second impedance matching circuit, and a second source coupled to the tunable resistor and a second inductor; and
a power source coupled to the first drain and the second drain.

11. The electronic device of claim 10, wherein the transmitter is configured to output an amplified signal for transmission by the one or more antennas via the second impedance matching circuit based on an input signal.

12. The electronic device of claim 10, wherein the tunable resistor is configured to provide an electrical resistance with a resistance value based on one or more control signals from a processor of the electronic device, the one or more control signals being indicative of a resistance value.

13. The electronic device of claim 12, wherein the tunable resistor comprises an array of transistors adjustable to provide the electrical resistance with the resistance value.

14. The electronic device of claim 10, wherein the first inductor and the second inductor are configured to inductively couple with a negative coupling factor during operation of the transmitter.

15. An electronic device comprising:
one or more antennas;
a receiver coupled to the one or more antennas, the receiver comprising
a first transistor having a first gate coupled to a first impedance matching circuit, a first drain coupled to a second impedance matching circuit, and a first source coupled to a tunable resistor and a first inductor, and
a second transistor having a second gate coupled to the first impedance matching circuit, a second drain coupled to the second impedance matching circuit, and a second source coupled to the tunable resistor and a second inductor; and
a power source coupled to the first drain and the second drain.

16. The electronic device of claim 15, wherein the receiver is configured to output an amplified received analog signal based on an analog signal received from the one or more antennas via the second impedance matching circuit.

17. The electronic device of claim 15, wherein the tunable resistor is configured to provide an electrical resistance with a resistance value based on one or more control signals from a processor of the electronic device, the one or more control signals being indicative of the resistance value.

18. The electronic device of claim 15, wherein the first transistor is configured to provide a first drain-to-source signal from the power source to the first inductor and the second transistor is configured to provide a second drain-to-source signal from the power source to the second inductor based on an input signal having a desired frequency.

19. The electronic device of claim 18, wherein the first inductor, the second inductor, and the tunable resistor form a resonant circuit, the resonant circuit configured to
ground direct current (DC) components of the first drain-to-source signal and the second drain-to-source signal, and
provide an electrical resistance to desired frequency components of the first drain-to-source signal and the second drain-to-source signal.

20. The electronic device of claim 19, wherein the resonant circuit is configured to ground one or more harmonic components of the first drain-to-source signal and the second drain-to-source signal.
